(19) United States
(12) Patent Application Publication
(10) Pub. No.: US 2025/0254821 A1
(43) Pub. Date: Aug. 7, 2025

(54) FAN DEVICE

(71) Applicant: IN WIN DEVELOPMENT INC., Taoyuan City (TW)

(72) Inventor: Wen-Hsien LAI, Taoyuan City (TW)

(73) Assignee: IN WIN DEVELOPMENT INC., Taoyuan City (TW)

(21) Appl. No.: 18/773,814

(22) Filed: Jul. 16, 2024

(30) Foreign Application Priority Data
Feb. 7, 2024 (TW) 113105063

(51) Int. Cl. H05K 7/20

(52) U.S. Cl. CPC H05K 7/20172

(57) ABSTRACT

A fan device is adapted to be coupled to an external electrical connector, and includes a housing unit, a blade unit, and a first electrical connector. The blade unit is rotatably disposed on the housing unit. The first electrical connector is adapted to be detachably coupled to the external electrical connector in one of a first connecting state and a second connecting state to receive electrical energy that is from the external electrical connector and that drives the blade unit to rotate. An orientation of the first electrical connector relative to the external electrical connector when the first electrical connector and the external electrical connector are in the first connecting state is opposite to an orientation of the first electrical connector relative to the external electrical connector when the first electrical connector and the external electrical connector are in the second connecting state.

### CROSS-REFERENCE TO RELATED APPLICATION

This application claims priority to Taiwanese Invention Patent Application No. 113105063, filed on Feb. 7, 2024, the entire disclosure of which is incorporated by reference herein.

### FIELD

The disclosure relates to a fan device, and more particularly to a fan device suitable for use in heat dissipation.

### BACKGROUND

Fans are often used as important heat dissipation devices in various electric motors and electronic devices. In the case of a personal computer, a fan may generate airflow to expel hot air from the personal computer so that a central processing unit (CPU) or a graphics processing unit (GPU) may function in a safe temperature range.

In many prior-art fan devices, a drive motor of a fan device is connected to a power connector (e.g., a common 4-pin connector, a common 3-pin connector) by a set of wires that are exposed from the fan device. Furthermore, a user has to connect the power connector to a male pin connector on a motherboard to supply electric power to the fan device.

However, the abovementioned design of the prior-art fan devices is actually easy to cause inconvenience when the user installs the fan device. For example, if the length of the set of wires is longer, the set of wires may easily be entangled with wires of internal components during installation. If the length of the set of wires is shorter, the flexibility of the installation of the fan device may be limited, or an additional extension wire may be necessary. In addition, because the set of wires is directly connected to an interior of the fan device, if the exposed wires are damaged by pulling or friction, it may cause inconvenience in repairing or replacing the exposed wires.

In view of what is mentioned above, how to improve the prior-art fan devices by minimizing the inconveniences becomes an issue to be discussed in the present application.

### SUMMARY

Therefore, an object of the disclosure is to provide a fan device that can alleviate at least one of the drawbacks of the prior art.

According to the disclosure, the fan device is adapted to be coupled to an external electrical connector and includes a housing unit, a blade unit, and a first electrical connector. The blade unit is rotatably disposed on the housing unit. The first electrical connector is adapted to be detachably coupled to the external electrical connector in one of a first connecting state and a second connecting state to receive electrical energy that is from the external electrical connector and that drives the blade unit to rotate. An orientation of the first electrical connector relative to the external electrical connector when the first electrical connector and the external electrical connector are in the first connecting state is opposite to an orientation of the first electrical connector relative to the external electrical connector when the first electrical connector and the external electrical connector are in the second connecting state.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a fragmentary front view illustrating an embodiment of a fan device according to the disclosure, and a power cable that is suitable for use with the embodiment.

FIG. 2 is a fragmentary, front, ride-side perspective view illustrating two protrusions, two pairs of engaging portions, an accommodating groove, and a first electrical connector of the embodiment.

FIG. 3 is a fragmentary, front, left-side perspective view illustrating two notches, two pairs of engagement portions, and a second electrical connector of the embodiment.

FIG. 4 is a schematic diagram illustrating a substrate, a first terminal row, and a second terminal row of the first electrical connector.

FIG. 5 is a fragmentary front view illustrating the embodiment, and a first external fan device and a second external fan device that are suitable for use in combination with the embodiment.

FIG. 6 is a fragmentary front view illustrating the embodiment in combination with the first and second external fan devices.

FIG. 7 is a fragmentary, top, sectional view taken along line VII-VII in FIG. 5, illustrating that the first electrical connector and one of the protrusions of the embodiment are respectively aligned with a second electrical connector and one of notches of the first external fan device.

FIG. 8 is a fragmentary, top, sectional view taken along line VIII-VIII in FIG. 6, illustrating the embodiment being in combination with the first external fan device.

FIG. 9 is a fragmentary, top, sectional view taken along line IX-IX in FIG. 5, illustrating that the second electrical connector and one of the notches of the embodiment are respectively aligned with a first electrical connector and one of protrusions of the second external fan device.

FIG. 10 is a fragmentary, top, sectional view taken along line X-X in FIG. 6, illustrating the embodiment being in combination with the second external fan device.

### DETAILED DESCRIPTION

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

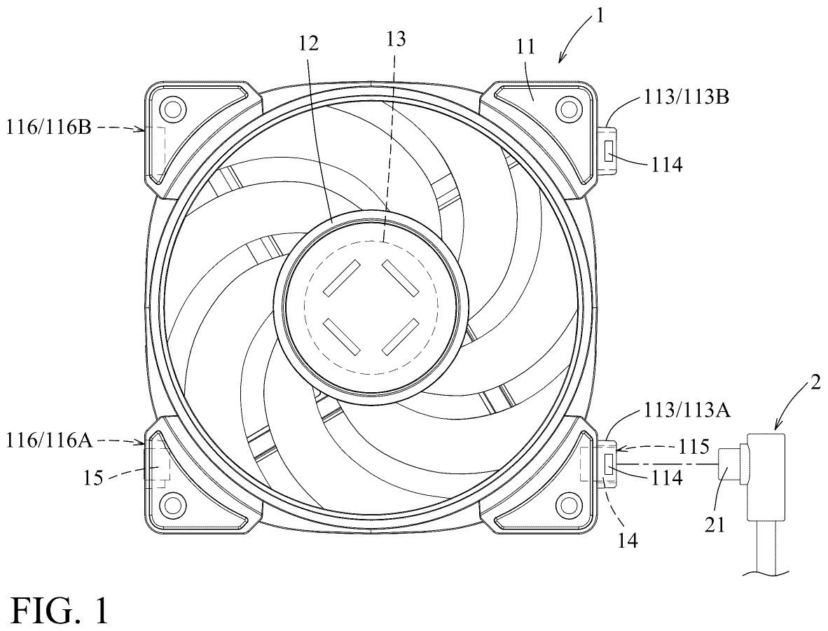

Referring to FIG. 1, an embodiment of a fan device 1 according to the disclosure is adapted to be coupled to an external electrical connector. In a first case of this embodiment, the external electrical connector is a power connector 21 of a power cable 2, and the power connector 21 is a male head of a specific hardware interface specification.

Referring to FIGS. 1, 2, and 3, the fan device 1 includes a housing unit 11, a blade unit 12 rotatably disposed on the housing unit 11, a drive motor 13 connected to the blade unit 12 for driving rotation of the blade unit 12, a first electrical connector 14 electrically coupled to the drive motor 13, and a second electrical connector 15 electrically coupled to the first electrical connector 14.

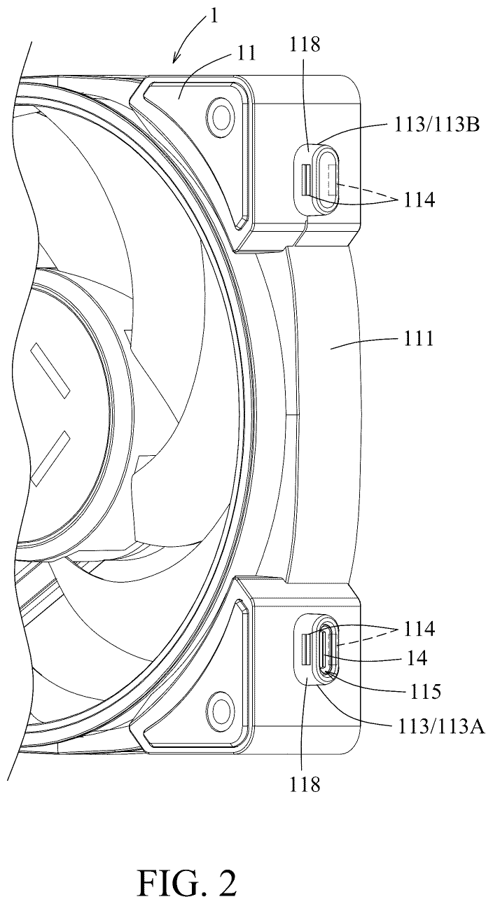

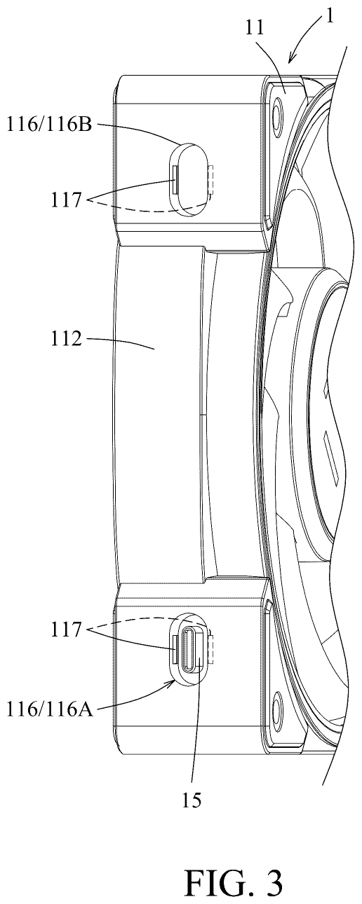

The housing unit 11 has a first side surface 111 (shown in FIG. 2), a second side surface 112 (shown in FIG. 3), two protrusions 113 located at the first side surface 111, two pairs of engaging portions 114 (shown in FIG. 2) respectively located at the two protrusions 113, an accommodating groove 115 formed in one of the protrusions 113, two notches 116 formed in the second side surface 112 (i.e., the notches 116 are located at the second side surface 112), and two pairs of engagement portions 117 (shown in FIG. 3) respectively located in the notches 116. The first and second side surfaces 111, 112 respectively face in two opposite directions (i.e., the second side surface 112 is opposite to the first side surface 111). If viewed from the perspective of FIG. 1, the first and second side surfaces 111, 112 respectively face in a right-side direction of the fan device 1 and a left-side direction opposite to the right-side direction.

The protrusions 113 are arranged in an up-down direction on the first side surface 111. Each of the protrusions 113 has an outer peripheral surface 118. Each of the pairs of the engaging portions 114 is formed in the outer peripheral surface 118 of the respective one of the protrusions 113 (i.e., each of the pairs of the engaging portions 114 is located at the outer peripheral surface 118 of the respective one of the protrusions 113). Specifically, in this embodiment, each of the pairs of the engaging portions 114 is a pair of grooves that are recessed from the outer peripheral surface 118 of the respective one of the protrusions 113, that extend along the first side surface 111, and that are elongated in the up-down direction. Furthermore, the engaging portions 114 in each of the pairs of the engaging portions 114 respectively face in two opposite directions, for example, a front-side direction of the fan device 1 and a rear-side direction opposite to the front-side direction.

For convenience of description, the protrusions 113 will hereinafter be respectively referred to as the protrusion 113A, and the protrusion 113B that is located above the protrusion 113A. In this embodiment, the accommodating groove 115 is formed on the protrusion 113A, and an opening of the accommodating groove 115 substantially faces in a same direction as the first side surface 111. The first electrical connector 14 is disposed on the first side surface 111, is located in the accommodating groove 115, protrudes away from the first side surface 111 but does not extend through the opening of the accommodating groove 115. In this way, the protrusion 113A may provide a protective effect to the first electrical connector 14 to prevent the first electrical connector 14 from being damaged by a foreign object that hits the fan device 1.

The notches 116 are arranged in the up-down direction on the second side surface 112. Openings of the notches 116 substantially face in a same direction as the second side surface 112. Moreover, in this embodiment, each of the pairs of the engagement portions 117 is a pair of engaging blocks that protrude from the respective one of the notches 116, that extend along the second side surface 112, and that are elongated in the up-down direction. The engagement portions 117 in each of the pairs of the engagement portions 117 correspond in position to each other in the respective one of the notches 116, and respectively face in the front-side direction and the rear-side direction. In one embodiment, the engagement portions 117 in each of the pairs of the engagement portions 117 are aligned in a front-rear direction.

For convenience of description, the notches 116 will hereinafter be respectively referred to as the notch 116A, and the notch 116B that is located above the notch 116A. In this embodiment, the second electrical connector 15 is disposed in the notch 116A so that the notch 116A may provide a protective effect to the second electrical connector 15 to prevent the second electrical connector 15 from being damaged by a foreign object that hits the fan device 1.

In this embodiment, the first electrical connector 14 is a connection socket (also referred to as a female head) of the specific hardware interface specification. Therefore, the first electrical connector 14 is adapted to be detachably coupled to the power connector 21. In addition, the second electrical connector 15 is a power connector (i.e., the male head) of a specific hardware interface specification. In other words, a structure of the second electrical connector 15 is substantially the same as that of the power connector 21. It should be noted that the first electrical connector 14 is electrically connected to the drive motor 13 and the second electrical connector 15 through conducting wires (not shown) that are disposed inside the housing unit 11. Furthermore, the first electrical connector 14 is used to receive external electrical energy (e.g., electrical energy from the power connector 21), and simultaneously provide the received electrical energy to the drive motor 13 and the second electrical connector 15. Through this, the drive motor 13 may use all of, or part of the electrical energy provided by the first electrical connector 14 to drive the blade unit 12 to rotate, and, the second electrical connector 15 may output part of the electrical energy received by the first electrical connector 14 therethrough to another external electrical connector when the second electrical connector 15 is coupled to the another external electrical connector (details of which will be described later).

It is supplementarily illustrated that the housing unit 11 further has a first mounting hole (not shown) that spatially communicates with the accommodating groove 115 for the first electrical connector 14 to extend therethrough, and a second mounting hole (not shown) that spatially communicates with the groove 116A for the second electrical connector 15 to extend therethrough. Furthermore, the first electrical connector 14 is electrically connected to the conducting wires that are in the housing unit 11 through the first mounting hole, and the second electrical connector 15 is electrically connected to the conducting wires that are in the housing unit 11 through the second mounting hole.

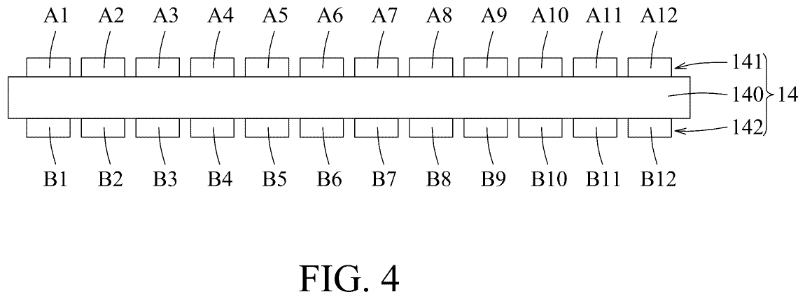

Referring to FIG. 4, the first electrical connector 14 includes a substrate 140, a first terminal row 141 disposed on one side of the substrate 140, and a second terminal row 142 disposed on another side of the substrate 140. The first terminal row 141 includes a plurality of first connecting terminals (A1) to (A12) arranged equidistantly in a straight line. The second terminal row 142 includes a plurality of second connecting terminals (B1) to (B12) arranged equidistantly in a straight line. In this embodiment, the first connecting terminals (A1) to (A12) of the first terminal row 141 and the second connecting terminals (B1) to (B12) of the second terminal row 142 are aligned with each other in the front-rear direction and are aligned with each other in a left-right direction (i.e., the first connecting terminals (A1) to (A12) on the substrate 140 respectively correspond in position to the second connecting terminals (B1) to (B12) on the substrate 140). In one aspect of the embodiment, pin assignments of the first connecting terminals (A1) to (A12) and pin assignments of the second connecting terminals (B1) to (B12) are shown in Table 1.

TABLE 1

| | | Second | |
|---|---|---|---|
| First connecting | | connecting | |
| terminals | Pin assignments | terminals | Pin assignments |
| A1 | GND | B1 | GND |
| A2 | N.C. | B2 | N.C. |
| A3 | N.C. | B3 | N.C. |
| A4 | V_BUS | B4 | V_BUS |
| A5 | V_SUP | B5 | CC2 |
| A6 | D− | B6 | D+ |
| A7 | D+ | B7 | D− |
| A8 | CC1 | B8 | V_SUP |
| A9 | V_BUS | B9 | V_BUS |
| A10 | N.C. | B10 | N.C. |
| A11 | N.C. | B11 | N.C. |
| A12 | GND | B12 | GND |

Referring to Table 1, each of the first connecting terminal (A1), the first connecting terminal (A12), the second connecting terminal (B1), and the second connecting terminal (B12) serves as a ground pin (GND pin). Each of the first and second connection terminals (A2), (A3), (A10), (A11), (B2), (B3), (B10), and (B11) serves as a not connected pin (N.C. pin). Each of the first connecting terminal (A4), the first connecting terminal (A9), the second connecting terminal (B4), and the second connecting terminal (B9) serves as a main power pin (V_BUS pin). Each of the main power pins is used for transmitting electricity at a 12 VDC rated voltage. Each of the first connecting terminal (A5) and the second connecting terminal (B8) serves as an auxiliary power pin (V_SUP pin). Each of the auxiliary power pins is used for transmitting the electricity at a 5 VDC rated voltage. Each of the first and second connecting terminals (A6) and (B7) serves as a negative pin (D−) for a differential signal. Each of the first and second connecting terminals (A7) and (B6) serves as a positive pin (D+) for the differential signal. Each of the first connecting terminal (A8) and the second connecting terminal (B5) serves as a direction-determining pin (CC1, CC2). Each of the direction-determining pins is used for determining a direction of a signal transmission between the first electrical connector 14 and the external electrical connector (e.g., the power connector 21).

It should be particularly noted that, referring to FIG. 4, in cooperation with Table 1, in addition to the arrangement that the first terminal row 141 and the second terminal row 142 are aligned with each other on the substrate 140, an order in which the pin assignments of the first connecting terminals (A1) to (A12) are arranged is opposite to an order in which the pin assignments of the second connecting terminals (B1) to (B12) are arranged (i.e., the arrangement of the second terminal row 142 on the substrate 140 is a result of flipping the arrangement of the first terminal row 141 on the substrate 140 in the left-right direction). In this way, referring to FIG. 1, the first electrical connector 14 is allowed to be detachably coupled to the power connector 21 in one of a first connecting state and a second connecting state. Furthermore, an orientation of the first electrical connector 14 relative to the power connector 21 when the first electrical connector 14 and the power connector 21 are in the first connecting state is opposite to an orientation of the first electrical connector 14 relative to the power connector 21 when the first electrical connector 14 and the power connector 21 are in the second connecting state. Specifically, FIG. 1 illustrates that the power connector 21 and the first electrical connector 14 are coupled in the first connecting state. The second connecting state represents a state in which the power connector 21 is coupled to the first electrical connector 14 after the power connector 21 is rotated 180 degrees about an axis (not shown) that extends in a direction in which the first electrical connector 14 protrudes. In other words, when the power connector 21 and the first electrical connector 14 are coupled in the second connected state, an orientation in which the power cable 2 is presented is upside-down relative to an orientation in which the power cable 2 is presented in FIG. 1. In this way, the first electrical connector 14 may be coupled to the power connector 21 in either of two opposite orientations. Because the first electrical connector 14 and the power connector 21 can still be correctly connected even if the orientation of one of the first electrical connector 14 and the power cable 2 is reversed, it is more convenient for installation of the fan device 1.

The first electrical connector 14 of the fan device 1 is detachably coupled to the external electrical connector (e.g., the power connector 21 in FIG. 1) of the specific hardware interface specification. Take the power connector 21 of the power cable 2 as an example: A user may install the fan device 1 to an electric motor or an electronic device (e.g., a personal computer) that requires heat dissipation, and then couple the power connector 21 to the first electrical connector 14 of the fan device 1, thereby preventing the power cable 2 from being entangled with other surrounding hardware during the installation of the fan device 1. Furthermore, even if the power cable 2 is damaged, the user may only need to replace the power cable 2 without disassembling the fan device 1. In addition, the user may freely choose the power cable 2 that has a proper length to power the fan device 1, so the fan device 1 has greater convenience and flexibility in terms of installation and maintenance.

Referring to FIGS. 1, 5, and 6 simultaneously, a second case of this embodiment is described below.

Different from the first case, the fan device 1 in the second case is coupled to two external electrical connectors. Specifically, the two external electrical connectors respectively belong to a first external fan device 1′ and a second external fan device 1″ (i.e., the first external fan device 1′ includes one of the external electrical connectors, and the second external fan device 1″ includes another one of the external electrical connectors) each of which has a same structure as the fan device 1.

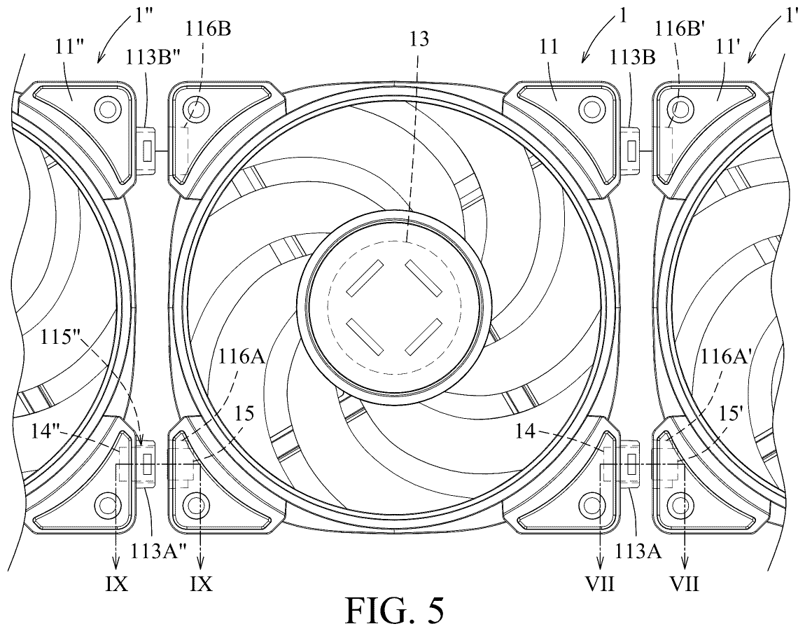

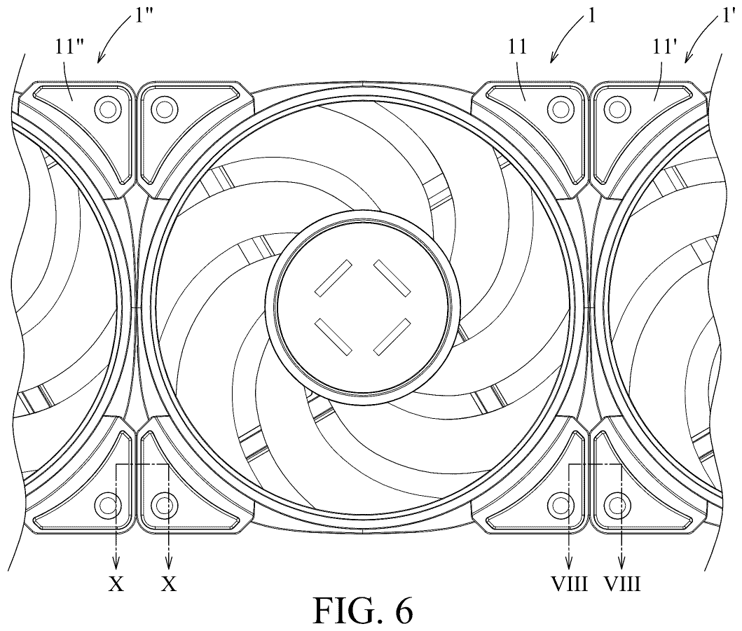

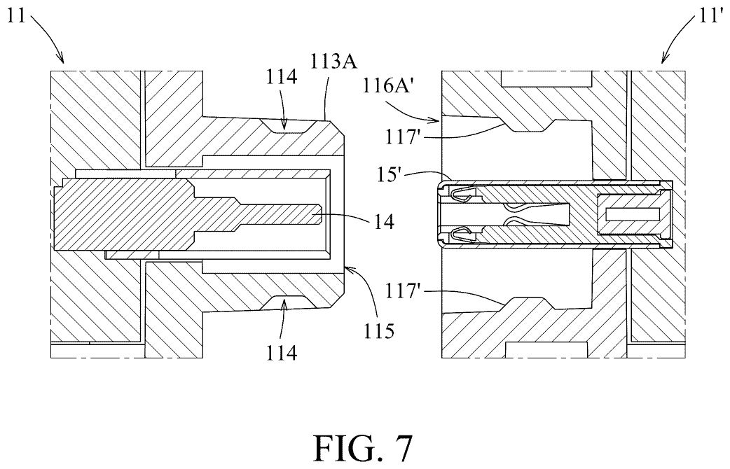

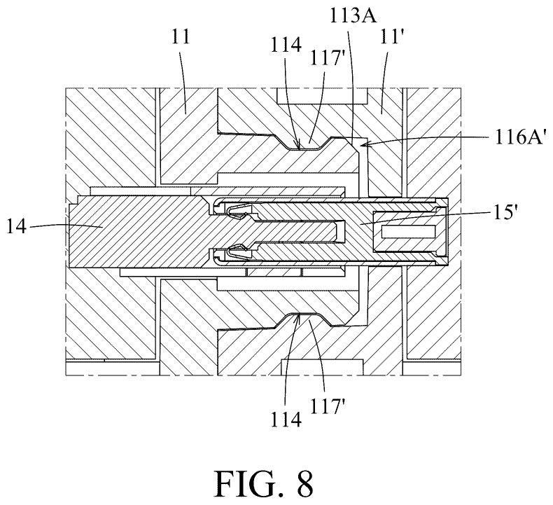

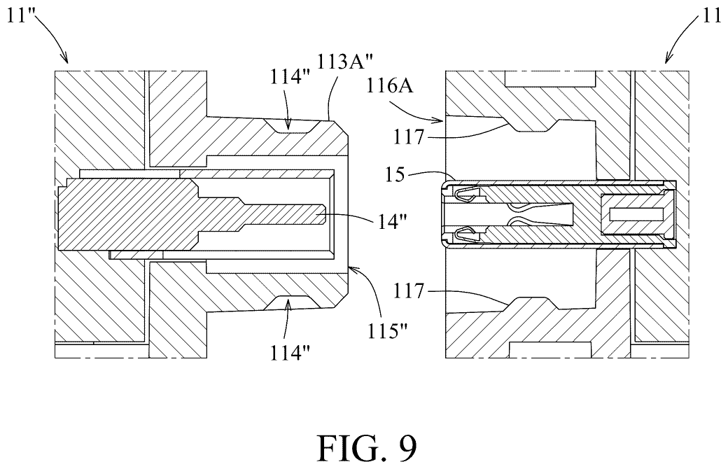

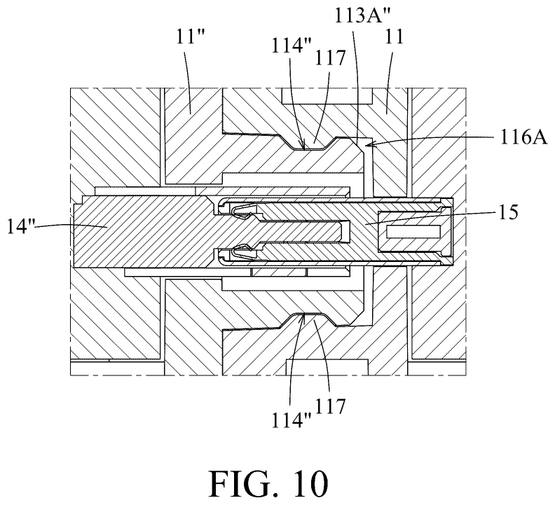

It is presented in FIG. 5 that the fan device 1, the first external fan device 1′, and the second external fan device 1″ are aligned with each other but are not yet combined with each other. FIG. 6 illustrates that the fan device 1, the first external fan device 1′, and the second external fan device 1″ are combined with each other. FIG. 7 is a result taken along a section line VII-VII that is shown in FIG. 5, and presents a portion of each of the fan device 1 and the first external fan device 1′ from a top view. FIG. 8 is a result taken along a section line VIII-VIII that is shown in FIG. 6 and shows the portion of each of the fan device 1 and the first external fan device 1′ from the top view. FIG. 9 is a result taken along a section line IX-IX that is shown in FIG. 5, and presents another portion of each of the fan device 1 and the second external fan device 1″ from the top view. FIG. 10 is a result taken along a section line X-X that is shown in FIG. 6, and presents the another portion of each of the fan device 1 and the second external fan device 1″ from the top view.

Referring to FIGS. 5, 7, and 8, the first external fan device 1′ includes a housing unit 11′ and a second electrical connector 15′. The housing unit 11′ has a notch 116A′, a notch 116B′, and two pairs of engagement portions 117′ that are respectively located in the groove 116A′ and the groove 116B′. FIGS. 7 and 8 only illustrate one of the pairs of the engagement portions 117′ that is located in the groove 116A′, and another one of the pairs of the engagement portions 117′ that is located in the groove 116B′ is not shown. Furthermore, as shown in FIG. 5, the second electrical connector 15′ is disposed in the notch 116A′.

Referring to FIGS. 5, 9, and 10, the second external fan device 1″ includes a housing unit 11″ and a first electrical connector 14″. The housing unit 11″ has a protrusion 113A″, a protrusion 113B″, an accommodating groove 115″ formed in the protrusion 113A″, and two pairs of engaging portions 114″ respectively located at the protrusion 113A″ and the protrusion 113B″. FIGS. 9 and 10 only illustrate one of the pairs of the engaging portions 114″ that is located at the protrusion 113A″. Furthermore, as shown in FIG. 5, the first electrical connector 14″ is disposed in the accommodating groove 115″.

Because the first external fan device 1′ and the second external fan device 1″ are substantially identical to the embodiment of the fan device 1, structural details of each of the first external fan device 1′ and the second external fan device 1″ will not be described in detail. Furthermore, as shown in FIG. 5, the one of the external electrical connectors that the first external fan device 1′ includes is the second electrical connector 15′ of the first external fan device 1′, and has a same structure as the second electrical connector 15 of the fan device, and the another one of the external electrical connectors that the second external fan device 1″ includes is the first electrical connector 14″ of the second external fan device 1″, and has a same structure as the first electrical connector 14 of the fan device 1.

A combination manner between the fan device 1 and the first external fan device 1′ is described below.

Referring to FIGS. 5 and 7, from the perspective of FIG. 5, the fan device 1 is adapted to be connected to a left side of the first external fan device 1′. A shape of the protrusion 113A and a shape of the protrusion 113B of the fan device 1 respectively match a shape of the notch 116A′ and a shape of the notch 116B′ of the first external fan device 1′. Furthermore, the protrusion 113A and the protrusion 113B of the fan device 1 are adapted to respectively engage the notch 116A′ and the notch 116B′ of the first external fan device 1′ such that the fan device 1 and the first external fan device 1′ are fixedly connected.

FIG. 7 illustrates that the protrusion 113A of the fan device 1 and the notch 116A′ of the first external fan device 1′ are aligned with each other but are not yet combined with each other. It should be noted that shapes of the engaging portions 114 that are located at the protrusion 113A respectively match shapes of the engagement portions 117′ that are located in the notch 116A′ of the first external fan device 1′.

Referring to FIGS. 6 and 8. FIG. 8 illustrates that the protrusion 113A of the fan device 1 engages the notch 116A′ of the first external fan device 1′. It should be noted that when the protrusion 113A of the fan device 1 engages the notch 116A′ of the first external fan device 1′, the engaging portions 114 in the pair of the engaging portions 114 that is at the protrusion 113A correspond in position to and engage the engagement portions 117′ in the pair of the engagement portions 117′ that is in the notch 116A′. Hence, the first external fan device 1′ and the fan device 1 are further fixed to each other. Moreover, when the protrusion 113A of the fan device 1 engages the notch 116A′ of the first external fan device 1′, the first electrical connector 14 of the fan device 1 is coupled to the second electrical connector 15′ of the first external fan device 1′ such that the electrical energy is transmitted between the first electrical connector 14 and the second electrical connector 15′.

It is supplementarily illustrated that the protrusion 113B of the fan device 1 and the notch 116B′ of the first external fan device 1′ are combined with each other in a same manner as how the protrusion 113A and the notch 116A′ are combined with each other, so it is not specifically illustrated in the drawings and will not be described.

The following is a combination manner between the fan device 1 and the second external fan device 1″.

Referring to FIGS. 5 and 9, from the perspective of FIG. 5, the fan device 1 is adapted to be connected to a right side of the second external fan device 1″. A shape of the notch 116A and a shape of the notch 116B of the fan device 1 respectively match a shape of the protrusion 113A″ and a shape of the protrusion 113B″ of the second external fan device 1″, and the notch 116A and the notch 116B of the fan device 1 are adapted for the protrusion 113A″ and the protrusion 113B″ of the second external fan device 1″ to respectively engage such that the fan device 1 and the second external fan device 1″ are fixedly connected.

FIG. 9 illustrates that a condition in which the notch 116A of the fan device 1 and the protrusion 113A″ of the second external fan device 1″ are aligned with each other but are not yet combined with each other. It should be noted that shapes of the engagement portions 117 that are located in the notch 116A respectively match shapes of the engaging portions 114″ that are located at the protrusion 113A″ of the second external fan device 1″.

Referring to FIGS. 6 and 10. FIG. 10 illustrates that the protrusion 113A″ of the second external fan device 1″ engages the notch 116A of the fan device 1. It should be noted that, when the protrusion 113A″ of the second external fan device 1″ engages the notch 116A of the fan device 1, the engaging portions 114″ in the pair of the engaging portions 114″ that is at the protrusion 113A″ correspond in position to and engage the engagement portions 117 in the pair of the engagement portions 117 that is in the notch 116A. Hence, the second external fan device 1″ and the fan device 1 are further fixed to each other. Moreover, when the protrusion 113A″ of the second external fan device 1″ engages the notch 116A of the fan device 1, the second electrical connector 15 of the fan device 1 is coupled to the first electrical connector 14″ of the second external fan device 1″ such that the electrical energy is transmitted between the second electrical connector 15 and the first electrical connector 14″.

Referring to FIGS. 5 and 6, by virtue of the fan device 1, the first external fan device 1′, and the second external fan device 1″ being combined with each other in series as shown in FIG. 6, when the first electrical connector 14′ (not shown) of the fan device 1′ receives the electrical energy such that the blade unit 12′ thereof can be driven to rotate and that the second electrical connector 15′ receives the electrical energy which the second electrical connector 15′ may output, the first electrical connector 14 of the fan device 1 may receive the electrical energy from the second electrical connector 15′ of the first external fan device 1′, and may provide part of the electrical energy to the drive motor 13 and another part of the electrical energy to the second electrical connector 15. Furthermore, as shown in FIG. 6, the second electrical connector 15 outputs the electrical energy received from the first electrical connector 14 to the first electrical connector 14″ of the second external fan device 1″ such that the second external fan device 1″ receives the electrical energy that can be used to drive the blade unit 12″ to rotate. Therefore, as shown in FIG. 6, the fan device 1, the first external fan device 1′, and the second external fan device 1″ function together. Based on the above description, the user can connect the embodiment of the fan device 1 to other fan devices in series according to his/her requirements. Therefore, the embodiment of the fan device 1 has good expansion flexibility.

It is supplementarily illustrated that, in certain embodiments, each of the engaging portions 114 of the fan device 1 may be an engaging block, and each of the engagement portions 117 may be an engaging groove. Therefore, specific configurations of the engaging portions 114 and the engagement portions 117 are not limited to what is disclosed in this embodiment. In addition, the specific hardware interface specification to which the first electrical connector 14 and the second electrical connector 15 belong is a special, self-defined specification in this embodiment. However, in certain embodiments, the specific hardware interface specification may adopt an existing universal specification, such as, but not limited to, USB Type-C.

In summary, the first electrical connector 14 of the fan device 1 is detachably coupled to the external electrical connector, thereby providing the fan device 1 with greater convenience and flexibility in terms of the installation and the maintenance. Furthermore, the fan device 1 may further be combined with other fan devices in series so it has good expansion flexibility. Thus, the purpose of the disclosure is indeed achieved.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A fan device adapted to be coupled to an external electrical connector, the fan device comprising:
a housing unit;
a blade unit rotatably disposed on the housing unit; and
a first electrical connector adapted to be detachably coupled to the external electrical connector in one of a first connecting state and a second connecting state to receive electrical energy that is from the external electrical connector and that drives the blade unit to rotate, wherein, an orientation of the first electrical connector relative to the external electrical connector when the first electrical connector and the external electrical connector are in the first connecting state is opposite to an orientation of the first electrical connector relative to the external electrical connector when the first electrical connector and the external electrical connector are in the second connecting state.

2. The fan device as claimed in claim 1, wherein the housing unit has a first side surface, a protrusion that is located at the first side surface, and an accommodating groove that is formed in the protrusion, the first electrical connector being located in the accommodating groove.

3. The fan device as claimed in claim 2, further adapted to be coupled to another external electrical connector, wherein:
the housing unit further has a second side surface that is opposite to the first side surface, and a notch that is formed in the second side surface; and
the fan device further comprises a second electrical connector that is electrically coupled to the first electrical connector, that is disposed in the notch, and that is adapted to be coupled to the another external electrical connector to output the electrical energy received by the first electrical connector therethrough to the another external electrical connector.

4. The fan device as claimed in claim 3, a first external fan device including the external electrical connector and having a same structure as the fan device, the external electrical connector having a same structure as the second electrical connector of the fan device and being disposed in a notch of the first external fan device, wherein a shape of the protrusion matches a shape of the notch of the first external fan device, the protrusion being adapted to engage the notch of the first external fan device such that the fan device and the first external fan device are fixedly connected, the first electrical connector being coupled to the external electrical connector of the first external fan device when the protrusion engages the notch of the first external fan device.

5. The fan device as claimed in claim 4, wherein the protrusion has an outer peripheral surface, the housing unit further having an engaging portion that is located at the outer peripheral surface of the protrusion, a shape of the engaging portion matching a shape of an engagement portion of the notch of the first external fan device, the engaging portion corresponding in position to the engagement portion of the notch of the first external fan device when the protrusion engages the notch of the first external fan device.

6. The fan device as claimed in claim 5, the first external fan device including two of the notches, wherein the housing unit includes two of the protrusions that are located at the first side surface, and the protrusions are adapted to respectively engage the notches of the first external fan device.

7. The fan device as claimed in claim 3, a second external fan device including the another external electrical connector and having a same structure as the fan device, the second external fan device having a protrusion and an accommodating groove that is formed in the protrusion thereof, the another external electrical connector being disposed in the accommodating groove of the second external fan device and having a same structure as the first electrical connector of the fan device, wherein a shape of the notch matches a shape of the protrusion of the second external fan device, the notch being adapted for the protrusion of the second external fan device to engage, the second electrical connector being coupled to the another external electrical connector of the second external fan device when the protrusion of the second external fan device engages the notch of the fan device.

8. The fan device as claimed in claim 7, wherein the housing unit further has an engagement portion that is located in the notch, a shape of the engagement portion matching a shape of an engaging portion of the protrusion of the second external fan device, the engagement portion corresponding in position to the engaging portion of the protrusion of the second external fan device when the protrusion of the second external fan device engages the notch.

9. The fan device as claimed in claim 8, the second external fan device including two of the protrusions, wherein the housing unit includes two of the notches that are located at the second side surface, and the notches are adapted for the protrusions of the second external fan device to respectively engage.
